(19) United States
(12) Patent Application Publication
(10) Pub. No.: US 2002/0132445 A1
(43) Pub. Date: Sep. 19, 2002

(54) METHOD FOR MANUFACTURING TRENCH ISOLATION TYPE SEMICONDUCTOR DEVICE

(76) Inventor: TAKAMICHI FUKUI, TOKYO (JP)

Correspondence Address: SUGHRUE MION ZINN MACPEAK & SEAS, 2100 PENNSYLVANIA AVE N W, WASHINGTON, DC, 20037

(21) Appl. No.: 09/249,098

(22) Filed: Feb. 12, 1999

(30) Foreign Application Priority Data
Feb. 13, 1998 (JP) 031447/1998

(51) Int. Cl. H01L 21/8242; H01L 21/20; H01L 21/76

(52) U.S. Cl. 438/424; 438/391; 438/248; 438/435

(57) ABSTRACT

In a method for manufacturing a trench isolation type semiconductor device, a trench is formed within a silicon substrate. Then, a first silicon oxide layer is formed only on a wall of the trench of the silicon substrate by thermally oxidizing the silicon substrate. Then, a second silicon oxide layer is deposited on the first silicon oxide layer by a chemical vapor deposition (CVD) process. Then, a third silicon oxide layer is deposited on the second silicon oxide layer by a plasma CVD process so that the third silicon oxide layer is completely filled in the trench. Then, the third silicon oxide layer outside of the trench is removed so that the third silicon oxide layer is buried in the trench. At least one of the first and second silicon oxide layers is thicker than approximately 60 nm.

### BACKGROUND OF THE INVENTION

1. Field of the Invention

The present invention relates to a method for manufacturing a trench isolation type semiconductor device.

2. Description of the Related Art

Generally, in a semiconductor device, a plurality of active areas in which active elements such as transistors are formed are isolated from each other by isolation areas. In the isolation areas, field silicon oxide layer are formed by using a local oxidation of silicon (LOCOS) process; however, such field silicon oxide layers cannot satisfy the requirements for more-fined semiconductor devices, since the field silicon oxide layers have so-called bird beaks.

Recently, trench isolation type semiconductor devices have been developed. That is, a trench (groove) is formed within a semiconductor substrate, and an insulating layer as an isolation layer is completely buried in the trench.

In a prior art method for manufacturing a trench isolation type semiconductor device, a trench is formed within a silicon substrate. Then, a first silicon oxide layer is formed only on a wall of the trench of the silicon substrate by thermally oxidizing the silicon substrate. Then, a second silicon oxide layer is deposited on the first silicon oxide layer by a chemical vapor deposition (CVD) process. Then, a third silicon oxide layer is deposited on the second silicon oxide layer by a plasma CVD process so that the third silicon oxide layer is completely filled in the trench. Then, the third silicon oxide layer outside of the trench is removed so that the third silicon oxide layer is buried in the trench. In this case, the first and second silicon oxide layers are both thinner than approximately 60 nm. This will be explained later in detail.

In the above-described prior art method, however, a part of the silicon substrate is exposed when the plasma CVD process is carried out so that the first and second silicon oxide layers are also etched by the plasma CVD process. As a result, the silicon substrate in the periphery of an isolation area is damaged by exposing it to the plasma atmosphere. Particularly the breakdown voltage and aging characteristics of a gate insulating layer are deteriorated, thus deteriorating the reliability of the device.

### SUMMARY OF THE INVENTION

It is an object of the present invention to improve the reliability of a trench isolation type semiconductor device.

According to the present invention, in a method for manufacturing a trench isolation type semiconductor device, a trench is formed within a silicon substrate. Then, a first silicon oxide layer is formed only on a wall of the trench of the silicon substrate by thermally oxidizing the silicon substrate. Then, a second silicon oxide layer is deposited on the first silicon oxide layer by a CVD process. Then, a third silicon oxide layer is deposited on the second silicon oxide layer by a plasma CVD process so that the third silicon oxide layer is completely filled in the trench. Then, the third silicon oxide layer outside of the trench is removed so that the third silicon oxide layer is buried in the trench. At least one of the first and second silicon oxide layers is thicker than approximately 60 nm.

Instead of this, a ratio of thickness of at least one of the first and second silicon oxide layers to that of the third silicon oxide layer is larger than approximately 10 percent. Further, the following condition is satisfied:

2·α+β≧0.23

where a is a ratio of thickness of the first silicon oxide layer to thickness of the third silicon oxide layer; and

β is a ratio of thickness of the second silicon oxide layer to thickness of the third silicon oxide layer.

As a result, the wall of the silicon substrate within the trench can be completely covered by the first and second silicon oxide layers.

### BRIEF DESCRIPTION OF THE DRAWINGS

The present invention will be more clearly understood from the description as set below, as compared with the prior art, with reference to the accompanying drawings, wherein:

FIGS. 1A through 1G are cross-sectional views for explaining a prior art method for manufacturing a trench isolation type semiconductor device;

FIG. 2 is a cross-sectional view of an enlargement of the device of FIG. 1D;

FIG. 3A is a plan view of a semiconductor device manufactured by using the method as illustrated in FIGS. 1A through 1G;

FIGS. 3B and 3C are cross-sectional views taken along the lines I-I and II-II, respectively, of FIG. 3A;

FIGS. 4A through 4G are cross-sectional views for explaining an embodiment of the method for manufacturing a trench isolation type semiconductor device;

FIG. 5A is a plan view of a semiconductor device manufactured by using the method as illustrated in FIGS. 4A through 4G; and

FIGS. 5B and 5C are cross-sectional views taken along the lines I-I and II-II, respectively, of FIG. 5A; and

FIG. 6 is a table for explaining the effect of the present invention and the prior art.

### DESCRIPTION OF THE PREFERRED EMBODIMENT

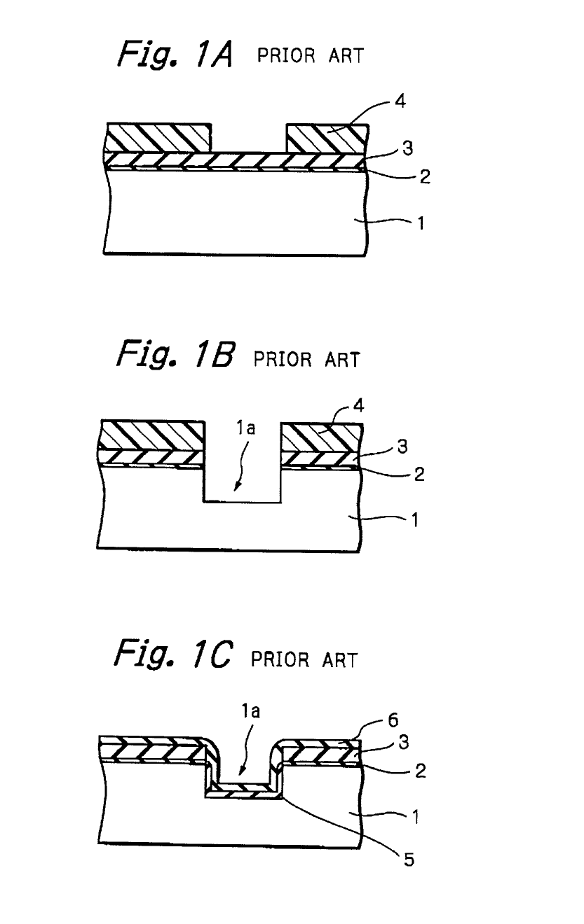

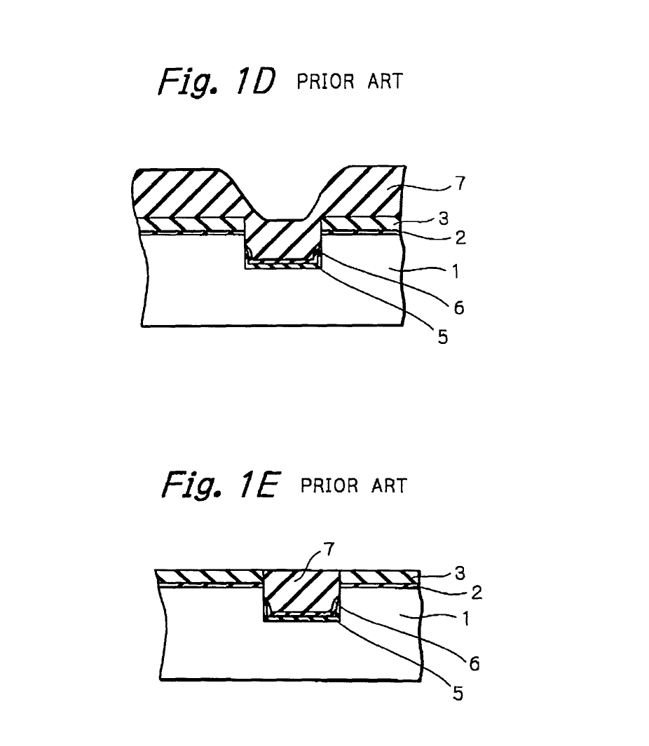

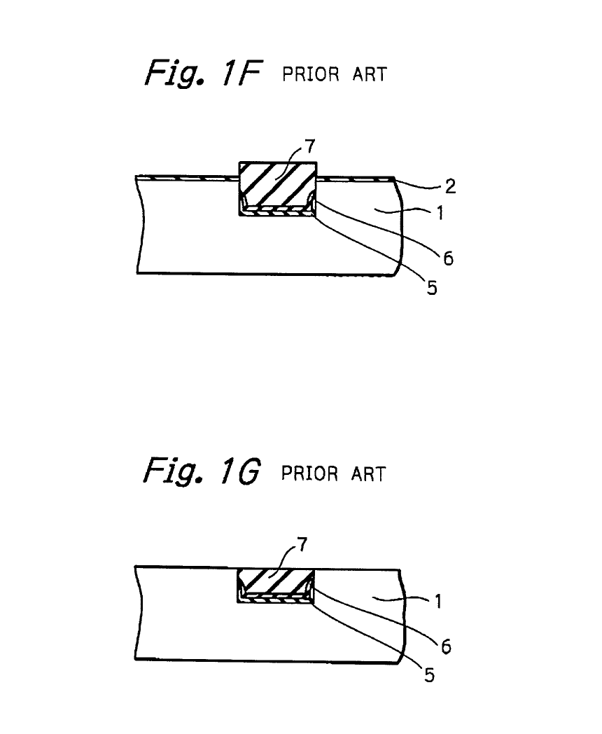

Before the description of the preferred embodiment, a prior art method for manufacturing a trench isolation type semiconductor device will be explained with reference to FIGS. 1A through 1G, 2, 3A 3B and 3C.

First, referring to FIG. 1A, an about 20 nm thick silicon oxide pattern layer 2 is grown by thermally oxidizing monocrystalline silicon substrate 1. Then, an about 150 nm thick silicon nitride layer 3 is deposited on the silicon oxide pattern layer 2. Then, a photoresist pattern layer 4 is formed on the silicon nitride layer 3.

Next, referring to FIG. 1B, the silicon nitride layer 3, the silicon oxide pattern layer 2 and the silicon substrate 1 are ethced by a dry etching process using the photoresist pattern layer 4 as a mask. As a result, an about 550 nm deep trench 1a is formed within the silicon substrate 1. Then, the photoresist pattern layer 4 is removed.

Next, referring to FIG. 1C, an about 20 nm thick silicon oxide layer 5 is grown within the silicon substrate 1 by thermally oxidizing the silicon substrate 1. In this case, the silicon oxide layer 5 is rounded at its edges, thus suppressing the fluctuation of characteristics of transistors formed in the device. Then, an about 20 nm thick silicon oxide buffer layer 6 is deposited on the entire surface by a CVD process.

Next, referring to FIG. ID, an about 600 nm thick silicon oxide isolation layer 7 is deposited on the entire surface by a plasma CVD process. In this case, the silicon oxide layer 6 on the silicon nitride layer 3 is etched, and also, the silicon oxide layers 6 and 5 within the trench 1a are etched.

Next, referring to FIG. 1E, the silicon oxide layer 7 is etched by a chemical mechanical polishing (CMP) process using, the silicon nitride layer 3 as a stopper. As a result, the silicon oxide layer 7 and the silicon nitride layer 3 become flat.

Next, referring to FIG. 1F, the silicon nitride layer 3 layer 2 is removed.

Finally, referring to FIG. 1G, the silicon oxide layers 7 and 2 are flattened by a CMP process on the like. As a result, the silicon oxide layer 7 is completely buried in the trench 1a of the silicon substrate 1. Thus, a trench-type isolation structure is completed.

Note that, after the above-mentioned processes are completed, a thin gate insulating layer and a gate electrode layer are formed, and impurity ions are implanted into the silicon substrate 1 to form impurity diffusion regions within the silicon substrate 1.

In the prior art method as illustrated in FIGS. 1A through 1G,

T1<60 nm (1)

T2<60 nm (2)

where T1 is the thickness of the silicon oxide layer 5; and

T2 is the thickness of the silicon oxide layer 6. Also,

R1<10% (3)

R2<1 % (4)

where R1 is the ratio of the thickness of the silicon oxide layer 5 to that of the silicon oxide layer 7; and

R2 is the ratio of the thickness of the silicon oxide layer 6 to that of the silicon layer 7.

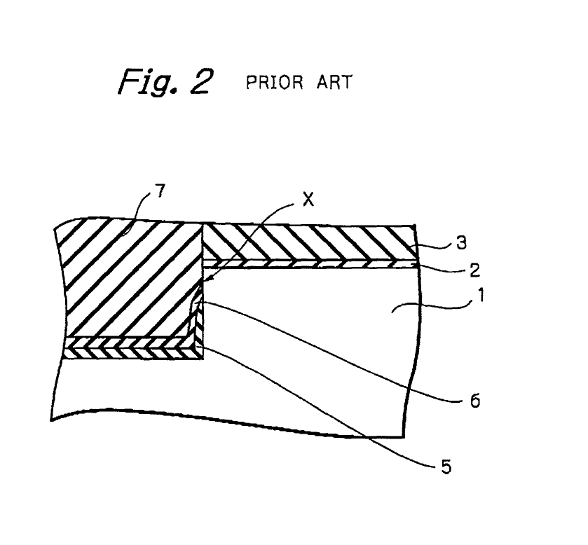

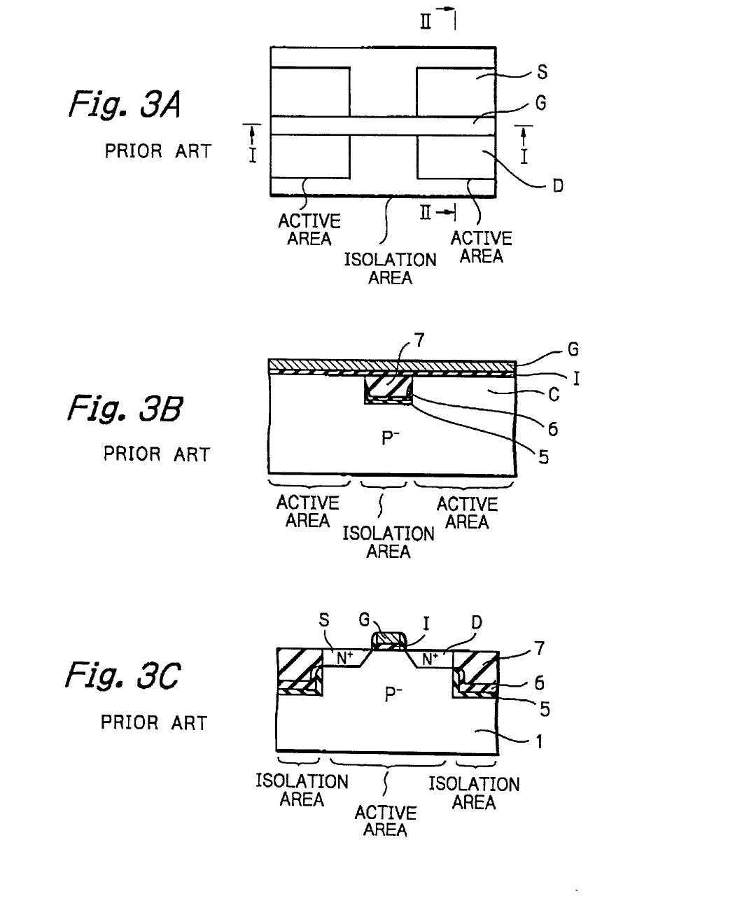

In the method as illustrated in FIGS. 1A through 1G, however, a part of the silicon substrate 1 as indicated by X in FIG. 2 is exposed, when the plasma CVD process is carried out so that the silicon oxide layers 6 and 5 are also etched by the plasma CVD process. As a result, as illustrated in FIGS. 3A, 3B and 3C, which illustrates a MOS transistor formed in the device manufactured by the method as illustrated in FIGS. 1A through 1G, the silicon substrate 1 in the periphery of an isolation area is damaged by exposing it the plasma atmosphere. Particularly, the breakdown voltage and aging characteristics of a gate insulating layer I are deteriorated, thus deteriorating the reliability of the device.

Note that FIGS. 3B and 3C are cross-sectional views taken along the lines I-I and II-II, respectively, of FIG. 3A. Also, in FIGS. 3A, 3B and 3C, G designates a gate electrode, C designates a channel region, S designates a source region, and D designates a drain region.

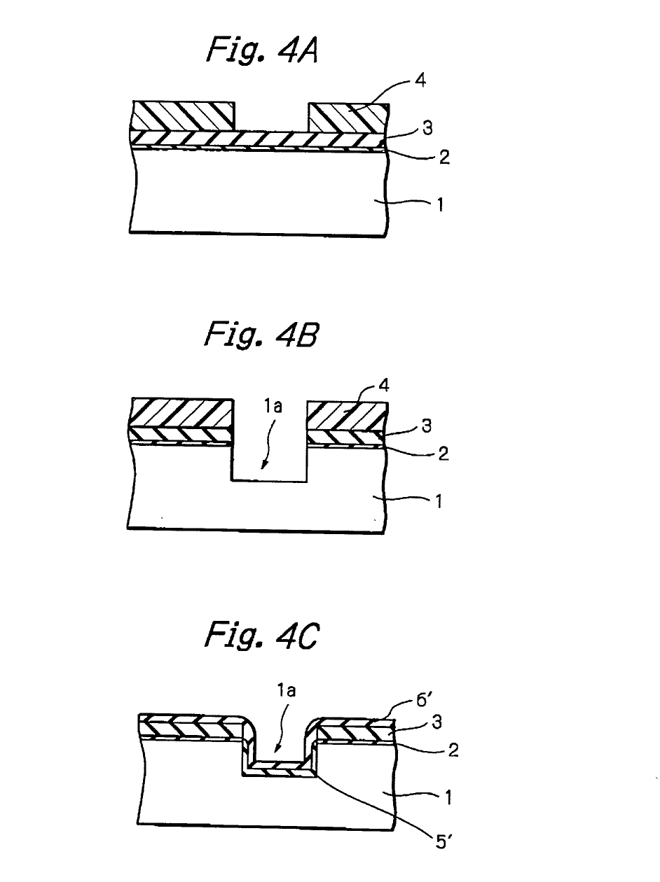

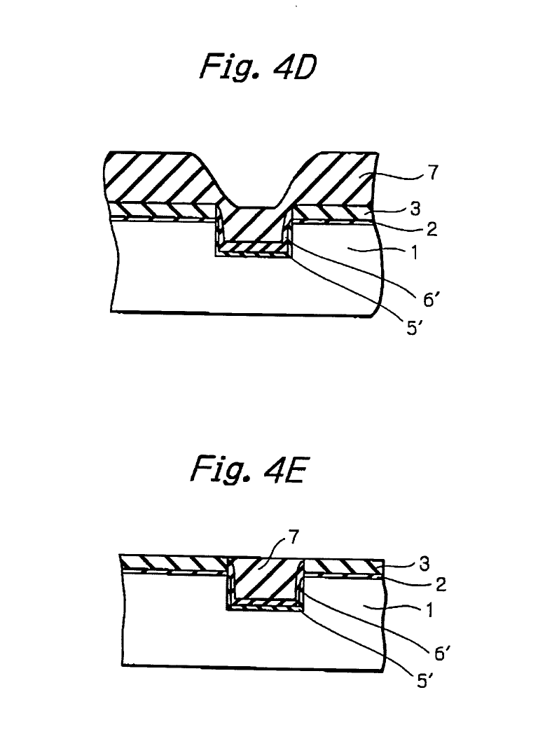

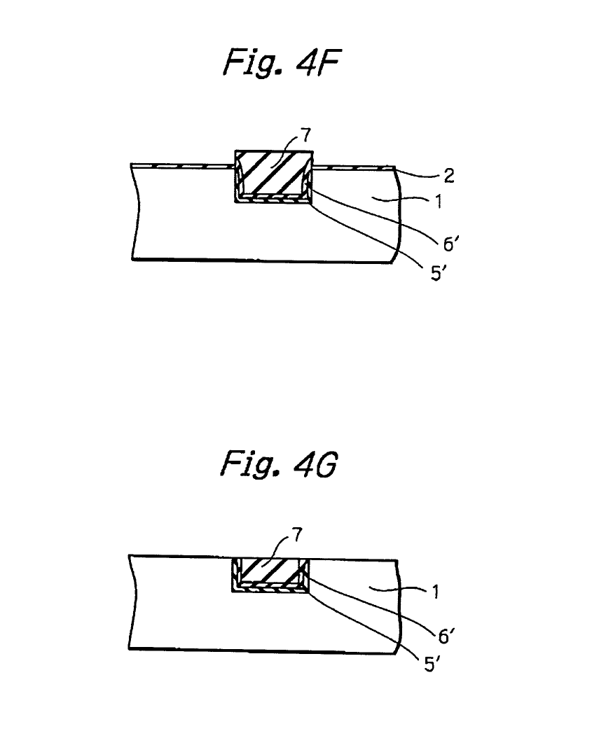

FIGS. 4A through 4G are cross-sectional views for explaining an embodiment of the method for manufacturing a trench isolation type semiconductor device.

First, referring to FIG. 4A, in the same way as in FIG. 1A, an about 20 nm thick silicon oxide pattern layer 2 is grown by thermally oxidizing monocrystalline silicon substrate 1. Then, an about 150 nm thick silicon nitride layer 3 is deposited on the silicon oxide pattern layer 2. Then, a photoresist pattern layer 4 is formed on the silicon nitride layer 3.

Next, referring to FIG. 4B, in the same way as in FIG. 1B, the silicon nitride layer 3, the silicon oxide pattern layer 2 and the silicon substrate 1 are ethced by a dry etching process using the photoresist pattern layer 4 as a mask. As a result, an about 550 nm deep trench 1a is formed within the silicon substrate 1. Then, the photoresist pattern layer 4 is removed.

Next, referring to FIG. 4C, in a similar way to that of FIG. 1C, an about 40 to 60 nm thick silicon oxide layer 5′ is grown within the silicon substrate 1 by thermally oxidizing the silicon substrate 1 under the condition that the substrate temperature is about 900 to 1200° C. and a water steam is used. In this case, the silicon oxide layer 5′ is rounded at its edges, thus suppressing the fluctuation of characteristics of transistors formed in the device. Then, an about 20 to 60 nm thick silicon oxide buffer layer 6′ is deposited on the entire surface by an atmospheric pressure CVD process under the condition that the substrate temperature is about 600 to 800° C.

Next, referring to FIG. 4D, in the same way as in FIG. ID, an about 600 nm thick silicon oxide isolation layer 7 is deposited on the entire surface by a plasma CVD process under the condition that the substrate temperature is about 200 to 300° C., the frequency is about 2 to 2.45 MHz, the power is about 2 KW, and the pressure is about 2 to 7 Torr. In this case, the silicon oxide layer 6′ on the silicon nitride layer 3 is etched, and also, the silicon oxide layers 6′ and 5′ within the trench 1a are etched. However, the edge of silicon substrate 1 is completely covered by the silicon oxide layers 6′ and 5′, so that the silicon substrate 1 is not exposed to the plasma atmosphere.

Next, referring to FIG. 4E, in the same way as in FIG. 1E, the silicon oxide layer 7 is etched by a CMP process using the silicon nitride layer 3 as a stopper. As a result, the silicon oxide layer 7 and the silicon nitride layer 3 become flat.

Next, referring to FIG. 4F, in the same way as in FIG. 1F, the silicon nitride layer 3 layer 2 removed.

Finally, referring to FIG. 4G, in the same way as in FIG. 1G, the silicon oxide layers 7 and 2 are flattened by a CMP process on the like. As a result, the silicon oxide layer 7 is completely buried in the trench 1a of the silicon substrate 1. Thus, a trench-type isolation structure is completed.

Note that, after the above-mentioned processes are completed, a thin gate insulating layer and a gate electrode layer are formed, and impurity ions are implanted into the silicon substrate 1 to form impurity diffusion regions within the silicon substrate 1.

In the method as illustrated in FIGS. 4A through 4G, at least one of the following conditions are satisfied:

T1′≧60 nm (5)

T2′≧60 nm (6)

where T1′ is the thickness of the silicon oxide layer 5′, and

T2′ is the thickness of the silicon oxide layer 6′. Also, at least one of the following conditions are satisfied:

R1′≧10% (7)

R2′>10% (8)

where R1′ is the ratio of the thickness of the silicon oxide layer 5′ to that of the silicon oxide layer 7′; and

R2′ is the ratio of the thickness of the silicon oxide layer 6′ to that of the silicon layer 7.

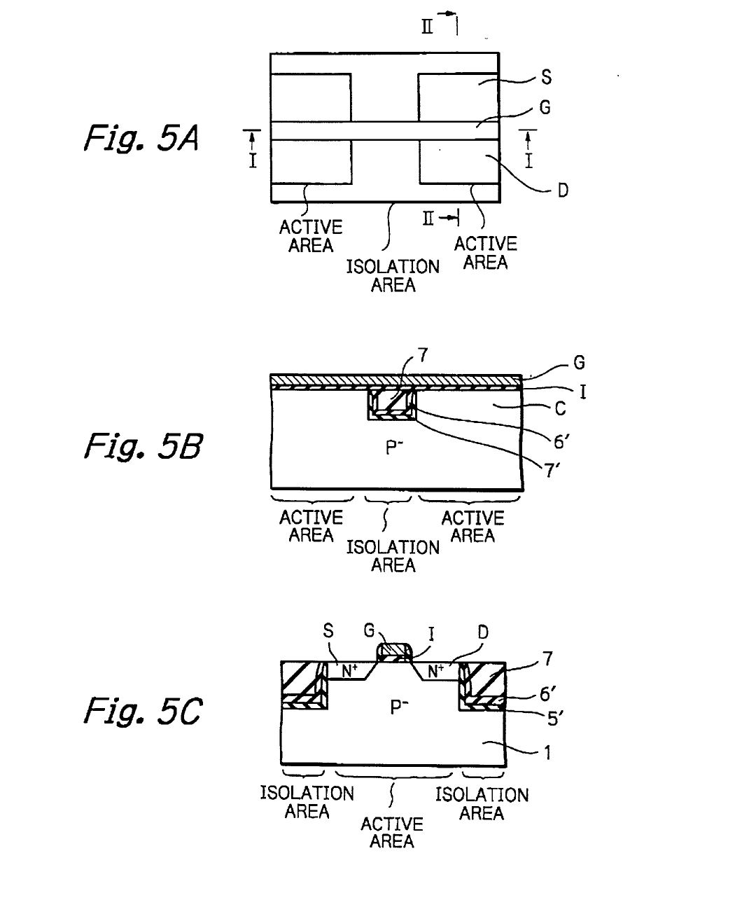

In the method as illustrated in FIGS. 4A through 4G, the silicon substrate 1 is never exposed, when plasma CVD process is carried out so that the silicon oxide layers 6 and 5 are also etched by the plasma CVD process. As a result, as illustrated in FIGS. 5A, 5B and 5C, which illustrates a MOS transistor formed in the device manufactured by the method as illustrated in FIGS. 4A through 4G, the silicon substrate 1 in the periphery of an isolation area is not damaged by exposing it the plasma atmosphere.

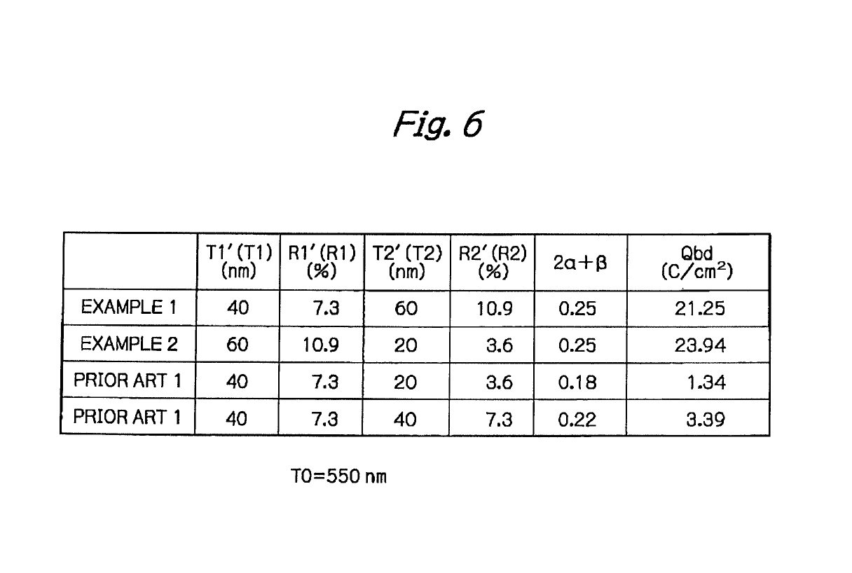

More specifically, as shown in FIG. 6, reliability tests are performed upon 100 trench isolation type semiconductor devices by injecting electrons thereinto. That is, when fifty devices of the 100 devices are broken, amounts Qbd of injected electrons therein are measured. In this case, the larger the electron amount Qbd, the higher the reliability. Note that the electron amount Qbd is preferably more than 10C/cm²

As shown in Example 1 of the present invention, when the thickness T1′ of the silicon oxide layer 5′ is 40 nm and the thickness T2′ of the silicon oxide layer 6′ is 60 nm, the electron amount is 21.25C/cm². Also, in Example 2 of the present invention, when the thickness T1′ of the silicon oxide layer 5′ is 60 nm and the thickness T2′ of the silicon oxide layer 6′ is 20 nm, the electron amount is 23.94C/cm².

On the other hand, as shown in Prior Art 1 of FIG. 6, when the thickness T1 of the silicon oxide layer 5 is 40 nm and the thickness T2 of the silicon oxide layer 6 is 20 nm, the electron amount Qbd is 1.34. Also, as shown in Prior Art 2 of FIG. 6, when the thickness T1 of the silicon oxide layer 5 is 40 nm and the thickness T2 of the silicon oxide layer 6 is 40 nm, the electron amount Qbd is 3.39.

That is, it is clear that Examples 1 and 2 of the present invention are excellent as compared with Prior Art 1 and 2.

In Examples 1 and 2 of the present invention, one of the thicknesses T1′ and T2′ is not smaller than 60 nm, which means that one of the conditions (5) and (6) is satisfied. In other words, one of the ratios R1′ and R2′ is not smaller than 10%, which means that one of the conditions (7) and (8) is satisfied.

In addition, when Example 1 of the present invention is compared with Example 2 of the present invention, since the electron amount Qbd of Example 2 is larger than the electron amount Qbd of Example 1, it is clear that the silicon oxide layer 5′ rather than the silicon oxide layer 6′ contributes to the reliability of the device. Here, if α is defined by T1′/T0 or T1/T0 and β is defined by T2′/T0 or T2/T0 where the thickness T0 of the silicon oxide layer 7 is 550 nm, a value of (2α+β) is 0.25 for Examples 1 and 2 of the present invention, while, the value of (2α+β)is 0.18 and 0.22 for Prior Arts 1 and 2, respectively. That is, the value (2α+β) is preferably larger than 0.23.

As explained hereinabove, according to the present invention, since the underlying silicon oxide layers are thick enough to cover the wall of the silicon substrate within its trench against the plasma atmosphere, the reliability of the device can be improved.

1. A method for manufacturing a trench isolation type semiconductor device, comprising the steps of:
forming a trench within a silicon substrate;
forming a first silicon oxide layer only on a wall of said trench of said silicon substrate by thermally oxidizing said silicon substrate;
depositing a second silicon oxide layer on said first silicon oxide layer by a chemical vapor deposition process;
depositing a third silicon oxide layer on said second silicon oxide layer by a plasma chemical vapor deposition process so that said third silicon oxide layer is completely filled in said trench; and
removing said third silicon oxide layer outside of said trench so that said third silicon oxide layer is buried in said trench,
at least one of said first and second silicon oxide layeres being thicker than approximately 60 nm.

2. A method for manufacturing a trench isolation type semiconductor device, comprising the steps of:
forming a trench within a silicon substrate;
forming a first silicon oxide layer only on a wall of said trench of said silicon substrate by thermally oxidizing said silicon substrate;
depositing a second silicon oxide layer on said first silicon oxide layer by a chemical vapor deposition process;
depositing a third silicon oxide layer on said second silicon oxide layer by a plasma chemical vapor deposition process to that said third silicon oxide layer is completely filled in said trench; and
removing said third silicon oxide layer outside of said trench so that said third silicon oxide layer is buried in said trench, a ratio of thickness of at least one of said first and second silicon oxide layers to that of said third silicon oxide layer being larger than approximately 10 percent.

3. A method for manufacturing a trench isolation type semiconductor device, comprising the steps of:
forming a trench within a silicon substrate;
forming a first silicon oxide layer only on a wall of said trench of said silicon substrate by thermally oxidizing said silicon substrate;
depositing a second silicon oxide layer on said first silicon oxide layer by a chemical vapor deposition process;
depositing a third silicon oxide layer on said second silicon oxide layer by a plasma chemical vapor deposition process so that said third silicon oxide layer is completely filled in said trench; and
removing said third silicon oxide layer outside of said trench so that said third silicon oxide layer is buried in said trench,
wherein 2·α+β≧0.23
where α is a ratio of thickness of said first silicon oxide layer to thickness of said third silicon oxide layer; and
β is a ratio of thickness of said second silicon oxide layer to thickness of said third silicon oxide layer.

4. A semiconductor device comprising:
a silicon substrate, a trench being formed within said silicon substrate;
a thermally-grown silicon oxide layer formed within said trench on said silicon substrate;
a chemical-vapor-deposition-grown silicon oxide layer; formed on said thermally-grown silicon oxide layer;and
a plasma-chemical-vapor-deposition-grown silicon oxide layer formed on said chemical-vapor-deposition-grown silicon oxide layer and being filled in said trench;
a wall of said silicon substrate within said trench being completely covered by said thermally-grown silicon oxide layer and said chemical-vapor-deposition-grown silicon oxide layer.

5. The device as set forth in claim 4, wherein at least one of said thermally-grown silicon oxide layer and said chemical-vapor-deposition-grown silicon oxide layer is thicker than approximately 60 nm.

6. The device as set forth in claim 4, wherein a ratio of thickness of at least one of said thermally-grown silicon oxide layer and said chemical-vapor-deposition-grown silicon oxide layer to thickness of said plasma-chemical-vapor-deposition-grown silicon oxide layer is larger than approximately 10 percent.

7. The device as set forth in claim 4,
wherein 2·α+β≧0.23
where α is a ratio of thickness of saud thermally-grown silicon oxide layer to thickness of the plasma-chemical-vapor-deposition-grown silicon oxide layer; and
β is a ratio of thickness of said chemical-vapor-deposition-grown silicon oxide layer to thickness of said plasma-chemical-vapor-deposition-grown silicon oxide layer.
